(19) United States
(12) Patent Application Publication
(10) Pub. No.: US 2026/0220512 A1
(43) Pub. Date: Jul. 30, 2026

(54) READOUT OF QUANTUM DEVICES

(71) Applicant: IQM FINLAND OY, Espoo (FI)

(72) Inventor: Andrew GUTHRIE, Espoo (FI)

(21) Appl. No.: 19/150,459

(22) PCT Filed: Jan. 26, 2024
(86) PCT No.: PCT/FI2024/050032

§ 371 Date: Jul. 23, 2025

(30) Foreign Application Priority Data
Jan. 27, 2023 (FI) 20235080

(51) Int. Cl. G06N 10/40; G01R 33/035; H01P 5/12; H01P 7/08

(52) U.S. Cl. CPC G06N 10/40; G01R 33/0354; H01P 5/12; H01P 7/088

(57) ABSTRACT

There is provided an quantum processing unit comprising a common probe line resonator; sub-probe line resonators coupled to the common probe line resonator; and quantum devices connected to the sub-probe line resonators, wherein the sub-probe line resonators are connected to the common probe line resonator by tunable coupler elements and each of the tunable coupler elements is configured to selectively couple an associated sub-probe line resonator to the common probe line resonator for readout of quantum devices connected to at least one selected sub-probe line resonator without readout from one or more non-selected sub-probe line resonators.

### TECHNICAL FIELD

The invention relates to the technical field of quantum computing. In particular, the invention relates to reading out states of a plurality of quantum devices in a quantum processing unit.

### BACKGROUND

A basic functional unit of quantum computing is the qubit, in the following also referred to as a quantum device, of which there may be a large number on a quantum processing unit. Throughout this description, the term quantum processing unit and its acronym QPU refer to a piece of hardware in which a plurality of circuit elements, at least some of which are suitable and designed for quantum computing, exist in a physical form suitable for being operated in the cryogenically cooled environment that is required for quantum computing. The term quantum circuit refers to a configurable abstraction of quantum gates performed during quantum computation. The term quantum computing system refers to a larger entity that comprises one or more QPUs, the control arrangement located outside the cryogenically cooled environment, and the signal paths between the two.

Each qubit used for a quantum computation assumes a superposition of two basis states. For concise reference, the superposition is often referred to as the quantum state, or simply just state, of the qubit. In general, a multi-qubit system is in a superposition of multi-qubit eigenstates.

In order to obtain a useful result of a quantum computation, a readout operation must be performed. The readout operation causes the quantum state of a single qubit to collapse into one of the possible basis states, resulting in a classical state that can be represented as a digital one or a digital zero. A representative characteristic of any quantum circuit is the coherence time, during which the readout operation must be performed to avoid losing the information represented by the quantum state.

A known way of performing a readout on a qubit involves using a readout resonator. The qubit is weakly coupled to an adjacent readout resonator, and the energy within the qubit causes, by means of qubit nonlinearity, a small shift in the scattering parameters of the combined system consisting of the qubit and the readout resonator. This shift can be detected by transmission of a so-called readout signal, which is a microwave pulse on resonance with the readout resonator.

Assuming that the qubit is a transmon, the interaction between the state of the qubit and the readout signal injected into the readout resonator causes an observable effect in the amplitude and phase of the transmitted signal. This effect is indicative of the classical state observed in the readout operation. From the readout resonator there are further signal paths that eventually transfer the obtained classical state out of the cryogenically cooled environment where the quantum processing unit resides.

The readout resonator must be located close to the qubit, the state of which is to be read. Building the signal paths between the readout resonator in the cryogenically cooled environment and the processing electronics in the surrounding room temperature environment is non-trivial, as it requires transmission lines operable at gigahertz frequencies with proper filtering and thermal anchoring to cold bodies in the cryostat. Frequency multiplexing may be utilized to share a common transmission line among about ten readout resonators in practice, the limit being related to readout speed and available bandwidth. Slower readout would allow more channels to be frequency-multiplexed if the hardware and software support it, but slower readout is against the overall goal of taking the best advantage of the limited coherence times of the qubits. In a system where the quantum processing unit comprises only a small number of qubits, these are not big problems. However, with the number of qubits in the quantum processing unit increasing it has been found that the physical space requirements of known readout systems as well as the conducted heat and cost related to a large quantity of wiring may become prohibitively large.

### SUMMARY

The scope of protection sought for various embodiments of the invention is set out by the independent claims. The embodiments, examples and features, if any, described in this specification that do not fall under the scope of the independent claims are to be interpreted as examples useful for understanding various embodiments of the invention.

It is an objective to overcome at least some of the problems identified above related to quantum computing.

According to a first aspect there is provided a quantum processing unit, comprising:
a common probe line resonator;
sub-probe line resonators coupled to the common probe line resonator; and
quantum devices connected to the sub-probe line resonators, wherein the sub-probe line resonators are connected to the common probe line resonator by tunable coupler elements and each of the tunable coupler elements is configured to selectively couple an associated sub-probe line resonator to the common probe line resonator for readout of quantum devices coupled to a selected sub-probe line resonator without readout from one or more non-selected sub-probe line resonators.

According to a second aspect there is provided a quantum computing system comprising a quantum processing unit according to an aspect.

According to a third aspect there is provided a method for the quantum computing system according to an aspect.

At least some aspects facilitate a space-efficient construction for large-scale quantum computing systems.

At least some aspects facilitate efficient readout for large-scale quantum computing systems.

### DESCRIPTION OF THE DRAWINGS

Other features and advantages of the invention will become apparent from the following description of a non-limiting example embodiment, with reference to the appended drawings, in which:

FIG. 1 illustrates a schematic example of a circuit for a quantum processing unit in accordance with at least some embodiments;

FIG. 2 illustrates a schematic example of a quantum computing system in accordance with at least some embodiments; and

FIG. 3 illustrates an example of a method in accordance with at least some embodiments.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilized, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

As used herein, “at least one of the following:” and “at least one of” and similar wording, where the list of two or more elements are joined by “and” or “or”, mean at least any one of the elements, or at least any two or more of the elements, or at least all the elements.

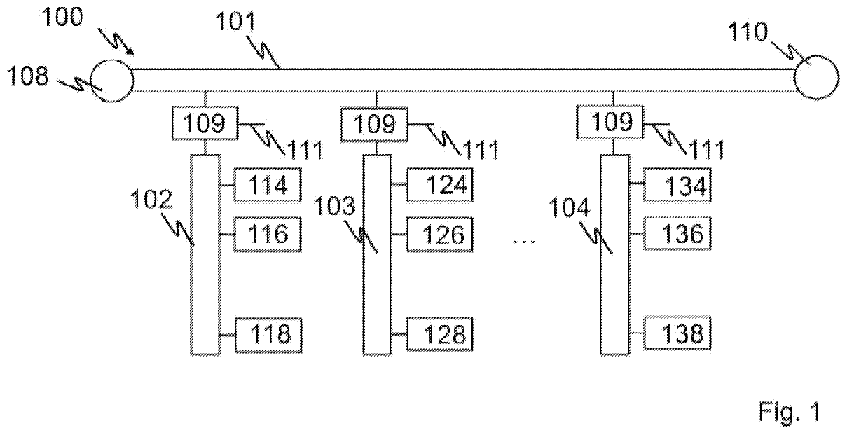

FIG. 1 illustrates a schematic example of a quantum processing unit 100. The quantum processing unit comprises a probe line resonator 101, i.e. a common probe line resonator, where one, two or more other probe line resonators 102, 103, 104, i.e. sub-probe line resonators, are connected to. The quantum processing unit comprises quantum devices, e.g. quantum bits or qubits, 114, 116, 118, 124, 126, 128, 134, 136, 138, connected to the sub-probe line resonators. Accordingly, readout of states of the quantum devices is performed via the common probe line resonator, or a common transmission line, and the sub-probe line resonators that are selectively coupled to the common probe line resonator. The coupling may be performed by selectively tuning the sub-probe lines resonators into resonance and off-resonance with the common probe line. Tuning of each of the sub-probe lines may be performed by coupler control signals that control the tunable coupler elements to be either in resonance with the common probe line resonator or off resonance with the common probe line resonator. The sub-probe line resonators 102, 103, 104 are connected to the common probe line resonator by tunable coupler elements 109 and each of the tunable coupler elements is configured to selectively couple an associated sub-probe line resonator 102, 103, 104 to the common probe line resonator 101 for readout of quantum devices connected to at least one selected sub-probe line resonator without readout from one or more non-selected sub-probe line resonators. In this way, the number of sub-probe line resonators that are coupled to the common probe line resonator at a given time may be controlled and the number of quantum devices readout at the given time may be limited to the number of quantum devices coupled to the selected at least one sub-probe line resonator. Therefore, efficient readout for large-scale quantum computing systems is facilitated. For example, only one sub-probe line resonator may be selected to be coupled to the common probe line resonator at a time for readout of states of the quantum devices connected to the selected sub-probe line resonator. In this way, the number of quantum devices coupled to the common probe line resonator may be limited to the number of quantum devices, e.g. ten quantum devices, coupled to the single selected sub-probe line resonator. It should be noted that since the readout of the quantum devices is performed via the common probe line resonator, readout can be performed using a common chain of readout electronics connected to the common probe line resonator. This facilitates space-efficient construction for quantum computing systems, where the number of quantum devices and the number of sub-probe line resonators is large.

It should be noted that the quantum devices 114, 116, 118, 124, 126, 128, 134, 136, 138 coupled to a sub-probe line resonator may be frequency multiplexed for the readout. The states of the quantum devices may be determined at a frequency band between 5.5 GHZ 6.5 GHz frequency band. Therefore, selectively coupling the sub-probe line resonators provides time division multiplexing of the sub-probe line resonators for the readout of the frequency multiplexed quantum devices of different sub-probe line resonators.

An example implementation of the quantum processing unit 100 comprises 10 sub-probe line resonators each of which is connected to 10 quantum devices, or qubits, whereby a total number of quantum devices becomes 100. Therefore, in the example implementation, 10% of the quantum devices can be readout simultaneously, whereby all the quantum devices may be readout in 2.2 μs<<T₁, where T₁ is the relaxation time of the quantum devices.

In an example in accordance with at least some embodiments, the quantum processing unit is configured to couple, by a tunable coupler element 109, the selected at least one sub-probe line resonator 102 to the common probe line resonator 101 for readout of quantum devices 114, 116, 118 connected to the selected sub-probe line resonator 102. In an example, each of the tunable coupler elements may be configured to couple an associated sub-probe line resonator 102, 103, 104 to the common probe line resonator 101 for readout of quantum devices 114, 116, 118, 124, 126, 128, 134, 136, 138 connected to the selected sub-probe line resonator 102. In this way the readout may be directed to those quantum devices that are connected to the selected sub-probe line resonator.

In an example in accordance with at least some embodiments, the quantum processing unit is configured to de-couple, by one or more of the tunable coupler elements 109, one or more non-selected sub-probe line resonators 103, 104 from the common probe line resonator for readout of quantum devices 114, 116, 118 connected to the at least one selected sub-probe line resonator 102. In this way successful readout from the selected at least one sub-probe line resonator is facilitated. In an example, if a sub-probe line resonator has not been selected, i.e. it is a non-selected sub-probe line resonator, a coupler associated to the non-selected sub-probe line resonator may de-couple the non-selected sub-probe line resonator from the common probe line resonator 101. It should be noted that the sub-probe line resonators may be by default de-coupled from the common probe line resonator.

In an example, each of the tunable coupler elements 109 may be controlled to couple its associated sub-probe line resonator 102, 103, 104 to the common probe line resonator or de-couple its associated sub-probe line resonator 102, 103, 104 from the common probe line resonator. When a tunable coupler element is coupled to its associated sub-probe line resonator, the tunable coupler element is switched on. When a tunable coupler element is de-coupled from its associated sub-probe line resonator, the tunable coupler element is switched off. It should be noted that the tunable coupler elements may be by default switched off, whereby switching on a tunable coupler element associated with the at least one selected sub-probe line resonator 102 facilitates readout of quantum devices 114, 116, 118 coupled to the at least one selected sub-probe line resonator 102 without readout from one or more non-selected sub-probe line resonators 103, 104. The tunable coupler elements may be controlled based on coupler control signals. In an example, the coupler control signals may be provided to the couplers via corresponding control lines 111. Each tunable coupler element may be connected to a control line for receiving a coupler control signal for controlling, e.g. tuning, the tunable coupler element. Implementation of the control line may be dependent on a type of the tunable coupler element. In an example, the tunable coupler element may be a SQUID, whereby the control line may be a radio-frequency (RF) flux line which facilitates fast control of the flux threading the squid loop. Coupling a given tunable coupler to the common probe line resonator may be performed by tuning the tunable coupler to

In an example in accordance with at least some embodiments, the tunable coupler elements 109 comprise tunable resonators, such as tunable inductors or tunable capacitors, comprising at least one of the following: quantum device connected in parallel with the associated sub-probe line resonator 102, 103, 104; or tunable superconducting quantum interference device (SQUID) loop connected in series with the sub-probe line resonator 102; or off-chip superconducting switching electronics; or a graphene gatemon connected in series with the sub-probe line resonator 102; or gated superconducting constriction connected in series with the sub-probe line resonator 102. In an example, a tunable resonator has an electrical length that can be tuned, or controlled, e.g. by an external control such as by a control arrangement. The electrical length of the tunable resonator can be e.g. increased or decreased by the external control. It should be noted that the graphene gatemon and the gated superconducting constriction may be controlled by using an electric field rather than a flux line. On the other hand, the tunable SQUID loop provides a simple implementation of the tunable resonator. In an example, each of the tunable resonators may be switched on separately from other tunable resonators. The SQUID is a very sensitive magnetometer used to measure extremely subtle magnetic fields based on superconducting loops containing Josephson junctions. The graphene gatemon is a voltage tunable transmon variant that employs locally gated nanowire superconductor-semiconductor Josephson Junctions for qubit control. The gated constriction is a form of Josephson junction formed by a very narrow constriction in a superconducting wire, whose inductance can be controlled by an electric field.

In an example, the common probe line resonator 101 may comprise an input terminal, or input port, 108 at one end of the common probe line resonator and an output terminal, or output port, 110 at another end of the common probe line resonator. An input signal chain may be connected to the input port and used for feeding an input signal to the common probe line resonator and to the tunable coupler elements. Similarly, an output signal chain may be connected to the output port and used for reading an output signal from the common probe line resonator. Since the readout of the quantum devices is performed via the common probe line resonator, the readout can be performed using a common input signal chain and an output signal chain for the quantum devices. It should be noted that it is viable to implement the input port and the output port using a single port.

In an example, the common probe line resonator 102 and sub-probe line resonators may be transmission line resonators, or waveguides. A transmission line resonator is capable of forming a standing wave at a resonance frequency. The sub-probe line resonators 102, 103, 104 may be selectively coupled to the common-probe line resonators by the tunable couplers 109. Accordingly, each of the sub-probe line resonators may be tuned to the resonance frequency of the common probe line resonator for coupling each of the sub-probe line resonators to the common probe line resonator. In this way a given sub-probe line resonator may switched on for readout of quantum devices coupled to the given sub-probe line resonator. On the other hand, each of the sub-probe line resonators may be de-tuned from the resonance frequency of the common probe line resonator for de-coupling each of the sub-probe line resonators to the common probe line resonator. In this way a given sub-probe line resonator may switched off, whereby readout of quantum devices coupled to the given sub-probe line resonator may be prevented.

In an example in accordance with at least some embodiments, the quantum devices, or qubits, comprise qubits such as superconducting qubits or spin-based qubits. Examples of the superconducting qubits comprise at least one of the following: a superconducting charge qubit; or a superconducting flux qubit; or a superconducting phase qubit; or a unimon qubit. The superconducting qubits may be implemented by Josephson junctions. Unimon qubit may comprise a coplanar waveguide, intercepted by at least one Josephson junction, and having a length between its two ends. Spin-based qubits have states that may be defined by spins of charge carriers (electrons and electron holes).

In an example, at a readout operation of quantum devices, one or more of the quantum devices 114, 116, 118, 124, 126, 128, 134, 136, 138 that are connected to a selected sub-probe line resonator are excited. Excitation of a quantum device causes an electromagnetic waveform to an associated readout resonator, i.e. the sub-probe line resonator 102, 103, 104, of the quantum device. The excitation of the quantum device changes the effective resonance frequency of the associated readout resonator. Hence, an electromagnetic waveform close to the resonant frequency of the readout resonator is reflected with a different amplitude and/or phase depending on the state of the quantum device. It should be noted that after the electromagnetic waveform has been reflected, the quantum device may remain excited. Therefore, the waveform has an electric field and a magnetic field that can be coupled to the sub-probe line resonator based on capacitive coupling and/or inductive coupling. Each of the readout resonators of the quantum devices may have a different resonant frequency, such that frequencies of a readout signal, or a probe signal, read from the common probe line resonator 101 may determine which quantum devices are actually read. Accordingly, the readout signal comprises waveforms of the determined quantum devices at a readout band. Therefore, the readout band comprises multiplexed resonator frequencies that are dispersively coupled to the quantum devices. Phase of the readout signal may be used for detecting states of qubits from the readout signal. It should be noted that depending on implementation, the probe line resonator may be measured in transmission and/or in reflection of the probe signal for reading the states of the quantum devices.

In an example, components of the quantum processing unit, such as quantum devices 114, 116, 118, 124, 126, 128, 134, 136, 138, resonators, common probe line resonator 101, sub-probe line resonators 102, 103, 14 and tunable coupler elements, can be made of superconductor materials. However, this is not an essential requirement, and other kinds of quantum technologies could be used for a quantum processing unit described herein. A superconductor material means here a material that can be made superconductive by cooling it to a sufficiently low temperature. An example of such materials is aluminium, but also other superconductor materials like molybdenum, niobium, tin, tantalum, or lead can be used. For operation, a superconductive quantum processing unit is cooled to a very low temperature, which can be some kelvins (K), or well under one kelvin, or in the order of some tens of millikelvins.

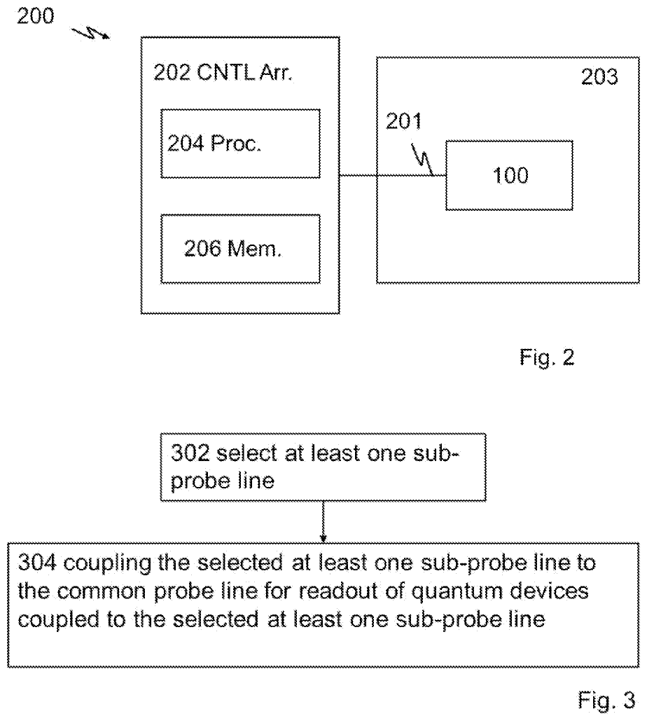

FIG. 2 illustrates a schematic example of a quantum computing system in accordance with at least some embodiments. The quantum computing system 200 comprises a quantum processing unit 100 in accordance to described with FIG. 1. In an example, the quantum processing unit comprises a common probe line resonator 101; sub-probe line resonators 102, 103, 104 connected to the common probe line resonator 101; and quantum devices 114, 116, 118, 124, 126, 128, 134, 136, 138 connected to the sub-probe line resonators 102, 103, 104, wherein the sub-probe line resonators 102, 103, 104 are connected to the common probe line resonator by tunable coupler elements and each of the tunable coupler elements is configured to selectively couple an associated sub-probe line resonator 102, 103, 104 to the common probe line resonator for readout of quantum devices 114, 116, 118 connected to at least one selected sub-probe line resonator 102 without readout from one or more non-selected sub-probe line resonators 103, 104. In an example, the quantum processing unit may be located in a cryogenically cooled environment 203.

In an example in an accordance with at least some embodiments, the quantum computing system 200 further comprises a control arrangement 202 operatively connected to the quantum processing unit 100 and the control arrangement is configured to cause one or more functionalities according to an example. It should be noted that the control arrangement may be operatively connected to at least one of the following elements of the quantum processing unit: common probe line resonator 101, tunable coupler elements 109 and quantum devices 114, 116, 118, 124, 126, 128, 134, 136, 138. In this way the control arrangement may feed one or more input signals to the quantum processing unit and read one or more output signals from the quantum processing unit. Connections 201 between the control arrangement and the quantum processing unit may be implemented by electrical connections. The connections may provide feeding one or more input signals to the quantum processing unit and reading one or more output signals from the quantum processing unit. In this way the control arrangement may provide at least one of the following: coupling control of sub-probe line resonators; input of coupling control signal; or de-coupling control of sub-probe line resonators; or readout control; or qubit control; or probe signal input; or reading readout signal.

In an example in an accordance with at least some embodiments, the control arrangement may be operatively connected to the quantum processing unit 100 and the control arrangement is configured to cause selecting at least one of the sub-probe line resonators 102, 103, 104 and coupling the selected at least one sub-probe line resonator 102 to the common probe line resonator 101 for readout of quantum devices 114, 116, 118 connected to the selected at least one sub-probe line resonator 102.

In an example, the control arrangement 202 comprises at least one processor 204. The at least one processor 204 may include, for example, one or more various processing devices such as a coprocessor, a microprocessor, a control unit, a Digital Signal Processor (DSP), processing circuitry with or without an accompanying DSP, or various other devices including integrated circuits such as, for example, an Application Specific Integrated Circuit (ASIC), a Field Programmable Gate Array (FPGA), a microprocessor unit (MCU), a hardware accelerator, a special-purpose computer chip, or the like.

In an example, the control arrangement 202 comprises at least one memory 206. The memory 206 may be configured to store, for example, one or more of coupling control signal(s), probe signal(s), tuning signal(s), computer program code, computer program instructions and computer programs.

Execution of the computer program code, computer program instructions and computer programs may cause at least one of the following for execution of one or more functionalities described herein: selecting sub-probe line resonator(s); or coupling the selected sub-probe line resonator(s); or de-coupling non-selected sub-probe line resonator(s); or reading readout signals; or determining states of one or more quantum devices; or determining an order for selecting sub-probe line resonators for readout; or changing selected sub-probe line resonator(s).

FIG. 3 illustrates an example of a method in accordance with at least some embodiments. The method provides efficient readout of a large-scale quantum computing system. The method may be performed by a quantum computing system described with FIG. 2, for example by the control arrangement 202.

Phase 302 comprises selecting at least one of the sub-probe line resonators 102, 103, 104.

Phase 304 comprises coupling the selected at least one sub-probe line resonator 102 to the common probe line resonator 101 for readout of quantum devices 114, 116, 118 connected the selected at least one sub-probe line resonator 102 without readout from one or more non-selected sub-probe line resonators 103, 104.

In an example in accordance with at least some embodiments, phase 304 comprises that the selected at least one sub-probe line resonator 102 is coupled to the common probe line resonator 101 by a tunable coupler element 109 of the selected at least one probe line resonator. In an example, the control arrangement may feed a coupler control signal to the tunable coupler element, which causes the tunable coupler element to be switched on for coupling the selected at least one sub-probe line resonator 102 to the common probe line resonator 101. It should be noted that the tunable coupler elements may be by default switched-off, whereby feeding the coupler control signal effectively determines, which of the tunable coupler element(s) are switched on and which of the tunable coupler elements are switched off.

In an example in accordance with at least some embodiments, phase 304 comprises de-coupling one or more non-selected sub-probe line resonators 103, 104 from the common probe line resonator 101, when the selected at least one sub-probe line resonator 102 is coupled to the common probe line resonator 101. Since the one or more non-selected sub-probe line resonators are de-coupled, only quantum devices coupled to the selected at least one sub-probe line resonator 102 may be read via the common probe line resonator. In an example, the non-selected one or more sub-probe line resonators 103, 104 are de-coupled from the common probe line resonator by tunable coupler elements 109 associated with corresponding non-selected sub-probe line resonators. In an example, the control arrangement may feed a coupler control signal to the tunable coupler elements 109 associated with corresponding non-selected sub-probe line resonators, which causes the one or more tunable coupler elements to be switched off for de-coupling non-selected sub-probe line resonators 103, 104 from the common probe line resonator 101. It should be noted that a coupling control signal may effectively serve for both which of the tunable coupler element(s) are switched on and which of the tunable coupler elements are switched off, if all the tunable coupler elements are by default switched-off.

In an example in accordance with at least some embodiments, phase 304 comprises reading a readout signal from the common probe line resonator 101, and determining states of one or more quantum devices 114, 116, 118 coupled to the selected at least one sub-probe line resonator 102 based on the readout signal. Since only the quantum devices of the selected at least one sub-probe line resonator are coupled to the common probe line resonator, the readout signal comprises only states of the quantum devices from the selected at least one sub-probe line resonator.

In an example, phase 302 comprises determining an order at which the sub-probe line resonators 102, 103, 104 are selected for readout and selecting the sub-probe line resonators at the determined order for readout. In this way readout may be performed from the sub-probe line resonators in the determined order. In an example, the order for selecting the sub-probe line resonators for readout may be determined based on an algorithm. For example, some algorithms may need only a part of the qubits to be read at a certain time, and the rest of the qubits may be read at another time. The qubits may be grouped into different probe line resonators based on their need for readout by the algorithm, such that execution of the algorithm at a certain time may be performed by reading a limited number of sub-probe line resonators, e.g. just one sub-probe line resonator, of all the sub-probe line resonators. For example, for a QPU comprising two sub-probe line resonators, qubits may be grouped based on an algorithm to the two different sub-probe line resonators. In this way, the qubits needed by the algorithm a certain time may are coupled to one of the two sub-probe line resonators, whereby readout of qubits from the other sub-probe line resonators may be omitted at that time, but performed later at another time. In an example, the sub-probe line resonators may be selected one at a time in their sequential order along the common probe line resonator 101. Accordingly, the sub-probe line resonator that is the closest to an input terminal 108 of the common probe line resonator may be selected first after which the sub-probe line resonator that is the second to closest to the input terminal may be selected. After the last sub-probe line resonator that is closest to an output terminal is selected, the sub-probe line resonator that is the closest to the input terminal may be selected again. In this way each of the probe line resonators is selected in turn for a uniform readout rate across the sub-probe line resonators.

In an example, phase 304 comprises changing the selected at least one sub-probe line resonator and reading a readout signal from selected one or more sub-probe line resonators at a time. In this way after the readout has been performed from the selected at least one sub-probe line resonator, the readout may be performed from other sub-probe line resonators. Accordingly, each sub-probe line resonator may be selected at a time and coupled to the common probe line resonator for readout of quantum devices connected to the selected sub-probe line resonator.

In an example in accordance with at least some embodiments, the quantum computing system 200 may comprise computer program code that when executed by a control arrangement 202 of the quantum computing system causes performance of one or more functionalities according to an example describe herein.

In an example in accordance with at least some embodiments, the quantum computing system 200 may comprise computer program code that when executed by a control arrangement of the quantum computing system causes selecting at least one of the sub-probe line resonators 102, 103, 104; and coupling the selected at least one sub-probe line resonator 102 to the common probe line resonator 101 for readout of quantum devices 114, 116, 118 connected to the selected at least one sub-probe line resonator 102 without readout from one or more non-selected sub-probe line resonators 103, 104. It should be noted that the computer program code can be stored in the memory 206 of the quantum computing system.

Any range or device value given herein may be extended or altered without losing the effect sought. Also, any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

LIST OF REFERENCE SIGNS

| | |
|---|---|
| Quantum processing unit | 100 |
| Common probe line resonator | 101 |
| Sub-probe line resonator | 102, 103, 104 |
| Probe line resonator terminals | 108, 110 |
| Tunable coupler element | 109 |
| Control line | 111 |
| Quantum devices | 114, 116, 118, |
| | 136, 138 |
| Quantum computing system | 200 |
| Control Arrangement | 202 |
| Processor | 204 |
| Memory | 206 |
| Connections | 201 |
| Cryogenically cooled environment | 203 |
| Phases of method of FIG. 3 | 302, 304 |

1. A quantum processing unit, comprising:
a common probe line resonator;
sub-probe line resonators coupled to the common probe line resonator; and
quantum devices connected to the sub-probe line resonators, wherein the sub-probe line resonators are connected to the common probe line resonator by tunable coupler elements, wherein each of the tunable coupler elements is configured to selectively couple an associated sub-probe line resonator to the common probe line resonator for readout of quantum devices connected to at least one selected sub-probe line resonator without readout from one or more non-selected sub-probe line resonators.

2. The quantum processing unit of claim 1, each of the sub-probe line resonators is coupled to more than one quantum device and the quantum processing unit is configured to cause:
time division multiplex coupling of the sub-probe line resonators to the common probe line resonator; and
readout of frequency multiplexed quantum devices coupled to a selected sub-probe line resonator via the common probe line resonator.

3. The quantum processing unit of claim 1, configured to:
couple, by a tunable coupler element, the selected at least one sub-probe line resonator to the common probe line resonator for readout of quantum devices connected to the selected sub-probe line resonator.

4. The quantum processing unit of claim 1, configured to:
de-couple, by one or more of the tunable coupler elements, one or more non-selected sub-probe line resonators from the common probe line resonator for readout of quantum devices connected to the at least one selected sub-probe line resonator.

5. The quantum processing unit of claim 1, wherein the tunable coupler elements comprise tunable resonators comprising at least one of the following: a quantum device connected in parallel with the associated sub-probe line resonator; or tunable superconducting quantum interference device, SQUID, loop connected in series with the sub-probe line resonator; or superconducting switching electronics; or a graphene gatemon connected in series with the sub-probe line resonator; or gated superconducting constriction connected in series with the sub-probe line resonator.

6. The quantum processing unit of claim 1, wherein at least one of the quantum devices is a superconducting qubit or a spin-based qubit.

7. A quantum computing system comprising the quantum processing unit of claim 1.

8. The quantum computing system of claim 7, further comprising a control arrangement operatively connected to the quantum processing unit and the control arrangement is configured to cause:
selecting at least one of the sub-probe line resonators;
coupling the selected at least one sub-probe line resonator to the common probe line resonator for readout of quantum devices connected to the selected at least one sub-probe line resonator without readout from one or more non-selected sub-probe line resonators.

9. The quantum computing system of claim 8, wherein the control arrangement is configured to cause:
de-coupling one or more non-selected sub-probe line resonators from the common probe line resonator, when the selected at least one sub-probe line resonator is coupled to the common probe line resonator.

10. The quantum computing system according to claim 8, wherein the control arrangement is configured to cause:
read a readout signal from the common probe line resonator;
determine states of one or more quantum devices coupled to the selected at least one sub-probe line resonator based on the readout signal.

11. The quantum computing system according to claim 8, wherein the control arrangement is configured to cause:
determine an order at which the sub-probe line resonators are selected for readout; and
select the sub-probe line resonators at the determined order for readout.

12. The quantum computing system according to claim 8, wherein the control arrangement is configured to cause:
change the selected at least one sub-probe line resonator;
read a readout signal from selected one or more sub-probe line resonators at a time.

13. A method for a quantum computing system comprising a quantum processing unit according to claim 1, comprising:
selecting, by the quantum computing system, at least one of the sub-probe line resonators;
coupling based on time division multiplexing of the sub-probe line resonators, by the quantum computing system, the selected at least one sub-probe line resonator to the common probe line resonator for readout of frequency multiplexed quantum devices connected to the selected at least one sub-probe line resonator without readout from one or more non-selected sub-probe line resonators.

14. The method of claim 13, comprising:
de-coupling, by the quantum computing system, one or more non-selected sub-probe line resonators from the common probe line resonator, when the selected at least one sub-probe line resonator is coupled to the common probe line resonator.

15. The method of claim 13, comprising:
reading, by the quantum computing system, a readout signal from the common probe line resonator;
determining, by the quantum computing system, states of one or more quantum devices coupled to the selected at least one sub-probe line resonator based on the readout signal.

16. The method of claim 13, comprising:
determining, by the quantum computing system, an order at which the sub-probe line resonators are selected for readout; and
selecting, by the quantum computing system, the sub-probe line resonators at the determined order for readout.

17. The method of claim 13, comprising:
changing, by the quantum computing system, the selected at least one sub-probe line resonator;
reading, by the quantum computing system, a readout signal from selected one or more sub-probe line resonators at a time.
